(19) United States
(12) Patent Application Publication
(10) Pub. No.: US 2013/0335933 A1
(43) Pub. Date: Dec. 19, 2013

(54) CIRCUIT BOARD AND ELECTRONIC DEVICE

(71) Applicant: KABUSHIKI KAISHA TOSHIBA, Tokyo (JP)

(72) Inventors: Norihiro ISHII, Tokyo (JP); Hiroki Matsushita, Kanagawa (JP)

(73) Assignee: Kabushiki Kaisha Toshiba, Tokyo (JP)

(21) Appl. No.: 13/779,518

(22) Filed: Feb. 27, 2013

(30) Foreign Application Priority Data
Jun. 15, 2012 (JP) 2012-136414

(51) Int. Cl. H05K 1/11

(52) U.S. Cl. CPC H05K 1/111
USPC 361/752; 174/260

(57) ABSTRACT

A circuit board includes a substrate having a mounting pad formed thereon, a packaged electronic device having a mounting surface coupled to the mounting pad and an electrode formed on a side surface of the packaged electronic device, and a conductive material that is disposed on a portion of the electrode formed on the side surface of the packaged electronic device and on a portion of the mounting pad. A first region of the pad is aligned with and adjacent to a portion of an outer edge of the electrode and includes the portion of the mounting pad. The second region of the pad is positioned between the mounting surface and the substrate and has at least one concave component that forms an insulating region. The circuit board can reduce the packaging height of parts and facilitate thinner electronic devices.

### CROSS-REFERENCE TO RELATED APPLICATION

This application is based upon and claims the benefit of priority from Japanese Patent Application No. 2012-136414, filed Jun. 15, 2012; the entire contents of which are incorporated herein by reference.

### FIELD

Embodiments described herein relate to a circuit board and an electronic device.

### BACKGROUND

It is important in electronic devices to control the packaging height of parts.

### DESCRIPTION OF THE DRAWINGS

FIG. 1 is a perspective view of a first electronic device according to an embodiment.

FIG. 2 is a plan view of a substrate in the first electronic device.

FIG. 3 is a perspective view of a second electronic device according to an embodiment.

FIG. 4 is a plan view of a substrate in the second electronic device.

FIG. 5 is a bottom plan view of a part to be packaged on a pad according to an embodiment.

FIG. 6 is a plan view of the pad according to the embodiment.

FIG. 7 is an enlarged plan view of the pad according to the embodiment.

FIG. 8 is a cross-sectional view of a circuit board in the embodiment.

FIG. 9 is a plan view of a first modified example of the pad according to the embodiment.

FIG. 10 is a plan view of a second modified example of the pad according to the embodiment.

FIG. 11 is a plane figure of a third modified example of the pad according to the embodiment.

### DETAILED DESCRIPTION

A circuit board and an electronic device, according to embodiments, reduce the packaging height of parts to enable thinner electronic devices to be manufactured.

Embodiments are described in reference to the drawings.

According to an embodiment, a circuit board includes a substrate having a mounting pad formed thereon, a packaged electronic device having a mounting surface coupled to the mounting pad and an electrode formed on a side surface of the packaged electronic device, and a conductive material that is disposed on a portion of the electrode formed on the side surface of the packaged electronic device and on a portion of the mounting pad. A first region of the pad is aligned with and adjacent to a portion of an outer edge of the electrode and includes the portion of the mounting pad. The second region of the pad is positioned between the mounting surface and the substrate and has at least one concave component that forms an insulating region. The circuit board can reduce the packaging height of parts and facilitate thinner electronic devices.

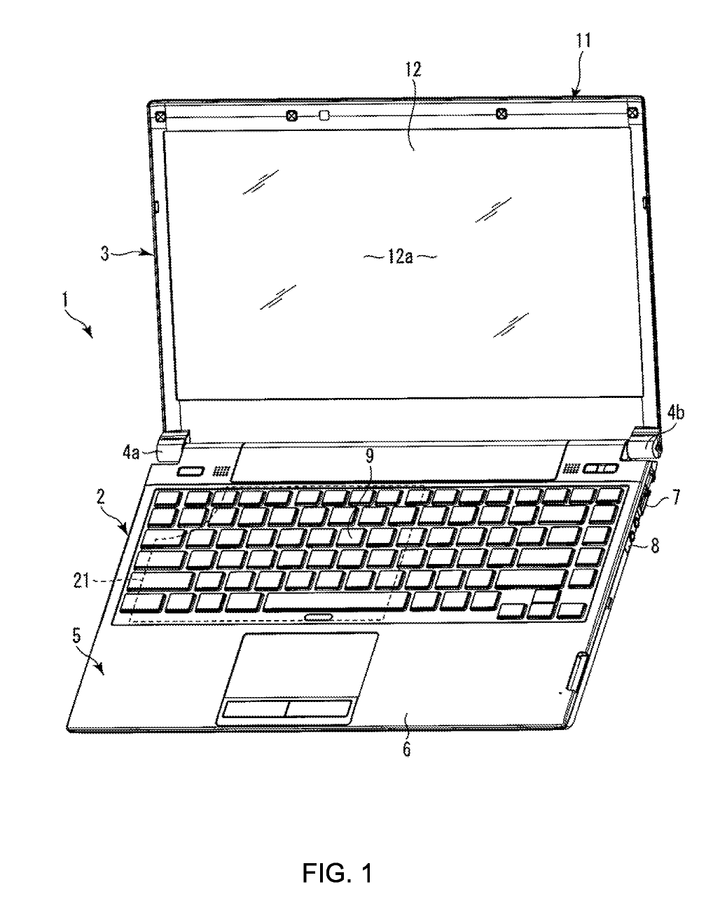

FIG. 1 illustrates a first electronic device 1 according to an embodiment. First electronic device 1 is, for example, a notebook type portable computer (notebook PC).

As shown in FIG. 1, the electronic device 1 includes a first subassembly 2, a second subassembly 3, and hinges 4a and 4b. First subassembly 2 is a primary assembly and includes, for instance, a main board, a packaged semiconductor substrate, a substrate assembly, and a printed circuit board 21. First subassembly 2 includes a first casing 5. The first casing 5 has an upper wall 6, a bottom wall 7 and a peripheral wall 8, and is formed into a shallow box.

When the first electronic device 1 is put on a desk, the bottom wall 7 will rest on the desk top surface. The upper wall 6 is positioned substantially parallel to the bottom wall 7 and is separated by a gap from the bottom wall 7. An input device 9, such as a keyboard, is disposed on the upper wall 6. Furthermore, the input device 9 is not limited to a keyboard, and may be a touch panel or other input device. The peripheral wall 8 substantially seals the gap between a rim of the bottom wall 7 and a rim of the upper wall 6.

As shown in FIG. 1, second subassembly 3 is, for instance, a display device, and is provided with a second casing 11 and a display unit 12 housed in the second casing 11. The display unit 12 may be, for instance, a liquid crystal display, but is not limited thereto. The display unit 12 has a display screen 12a for displaying images.

Second casing 11 is connected in hinged fashion (i.e., capable of opening and closing) at an edge of first casing 5 by hinges 4a and 4b. In this way, the electronic device 1 can be folded between a first position where first subassembly 2 and second subassembly 3 are closed and a second position where first subassembly 2 and second subassembly 3 are opened. In the second position, the input device 9 of first subassembly 2 and display screen 12a of second subassembly 3 are exposed.

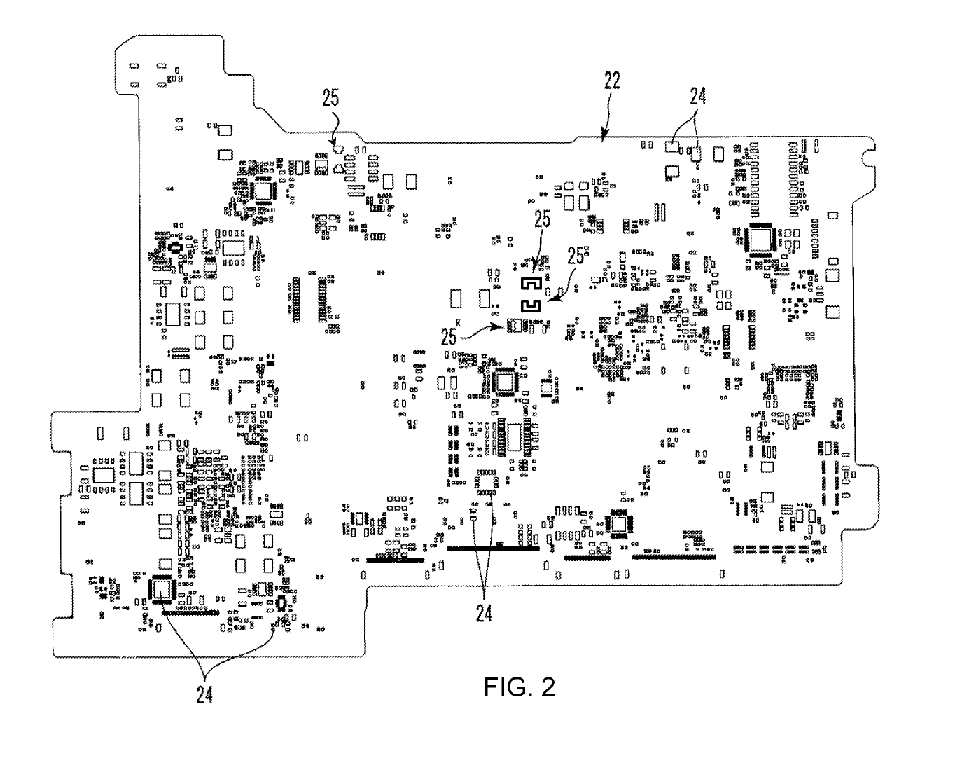

A printed circuit board 21 shown in FIG. 2 is housed in first casing 5 of first subassembly 2. Printed circuit board 21 includes a substrate 22 with packaged electronic devices 23 (e.g., electronic parts, semiconductor devices, and the like) mounted thereto. The substrate 22 includes multiple pads 24 formed thereon. These pads 24 include a pad 25 that is configured for low package height when a packaged electronic device 23 is mounted thereon and includes at least one concave component, which may also be referred to as a notched component, a depression, an insulating region, or a flow-guiding component. The pad 25 is configured to allow low package height (hereinafter, referred to simply pad 25) and is positioned in a region of substrate 22 where the height of components on substrate 22 is kept to a minimum.

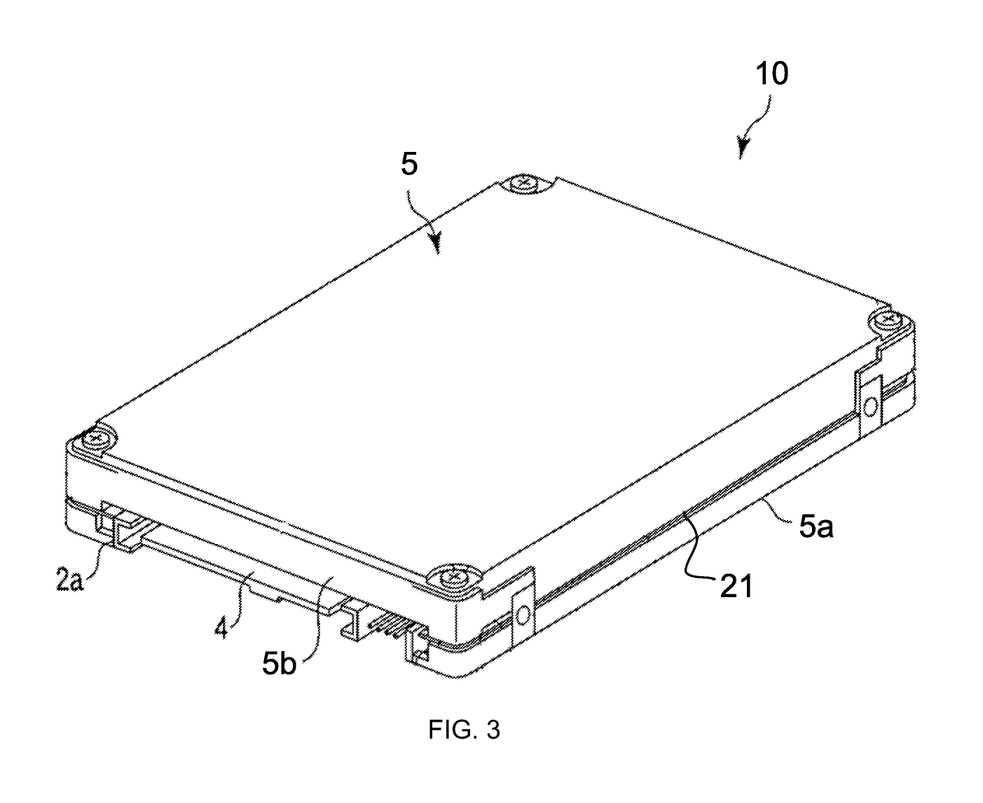

SSD (Solid State Drive) 10, which is a second electronic device according to an embodiment, is shown in FIG. 3. SSD 10 is a memory unit and is another example of electronic device. Although the notebook PC and SSD are illustrated as electronic devices herein, the present embodiment is also applicable to other electronic devices and is not limited to those described herein. The present embodiment can be generally applied to various electronic devices, including television receiver sets, portable telephones, smart phones, electronic tablets, electronic gaming devices, etc.

As shown in FIG. 3, SSD 10 includes casing 5 and printed circuit board (main board, circuit board, part-mounted substrate, substrate assembly, substrate unit) 21 housed in the casing 5. The printed circuit board 21 has a connector 4, which is for external connections. This connector 4 is exposed to the outside through opening 2a of casing 5. SSD 10 is configured as a modular unit, and is loaded with various information processing devices.

The casing 5 has a base 5a (bottom cover) and a base 5b (top cover).

Printed circuit board 21 is an example of a “circuit board”. Printed circuit board 21 has a first face 21a and a second face (not shown). The first face 21a is, for instance, a bottom face and is oriented toward base 5a. The second face is, for instance, a top face and is oriented toward cover 5b.

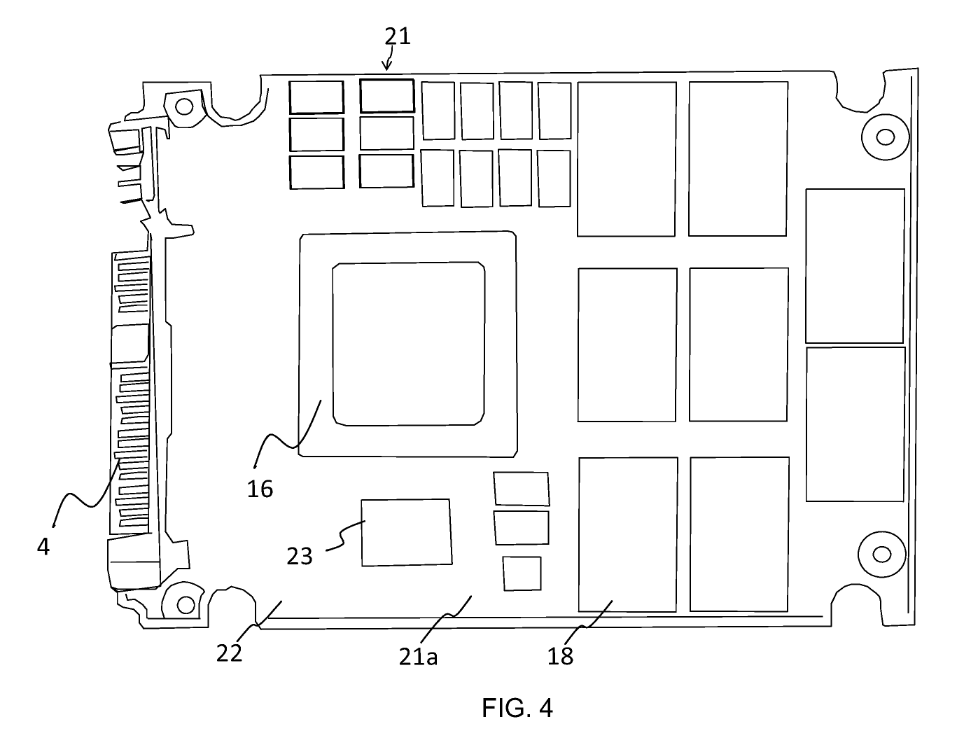

As shown in FIG. 4, on first face 21a control IC 16, multiple NAND type memory units 18, and packaged electronic devices 23 (packaged semiconductor chips, electronic components, functional components, surface packaging components, LGA, resistors, transistors, etc.) are mounted and electrically connected to each other as elements of circuits. In addition, packaged electronic device 23, multiple NAND type memory chips 18, and connector 4 are also mounted on the first face 21a. Alternatively, packaged electronic device 23 and multiple NAND type memory chips 18 may be mounted on the second face.

As shown in FIG. 2, substrate 22 shown in FIG. 4 has multiple pads 24, and those pads 24 include a pad 25 provided with at least one concave portion. Next, an explanation is given of the configuration of pad 25.

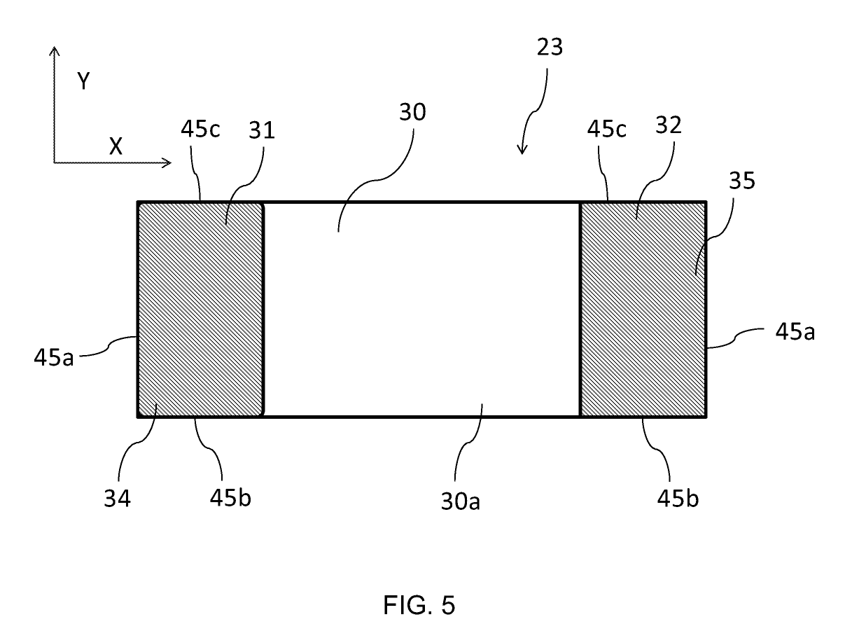

FIG. 5 shows an example of packaged electronic device 23 that may be mounted on pad 25, as viewed from the rear surface side (i.e., the bottom surface side or the mounting surface side). The packaged electronic device 23 is, for instance, a packaged semiconductor chip, and may have a semiconductor encapsulated in a package body 30 and first and second electrodes 31 and 32 are formed in the package body 30. The package body 30 acts as a case that protects the semiconductor of the packaged electronic device 23, since the semiconductor is encapsulated therein.

As shown in FIG. 5, the package body 30 is formed into a substantially rectangular shape and has a rear surface 30a that is oriented toward substrate 22. The rear surface 30a is an example of a “substrate-contacting surface” of package body 30. The package body 30 has a first end 34 and second end 35, where the later is positioned at the side of package body 30 that is opposite to first end 34.

First electrode 31 is formed at first end 34 of the package body 30. The first electrode 31 extends along the edge of first end 34. An example of first electrode 31 is a signal lead or signal terminal. Second electrode 32 is formed at second end 35 of the package body 30. The second electrode 32 extends along the edge of second end 35. An example of the second electrode 32 is a lead for grounding, such as a ground terminal. Another example of second electrode 32 may be an electrode for power supply.

As shown in FIG. 5, the packaged electronic device 23 has an electrode structure that includes the first electrode and the second electrode, which are disposed symmetrically on opposite sides of the center (or center portion) of the rear surface 30a. Examples of the packaged electronic device 23 include a resistor, a Field Effect Transistor (FET), a Logic Gate Array (LGA), etc. A part of first electrode 31 and a part of second electrode 32 form portions of the rear surface 30a. Second electrode 32 may be an electrode having, for example, an area wider than first electrode 31, and may be strengthened when a ground connection to reduce noise.

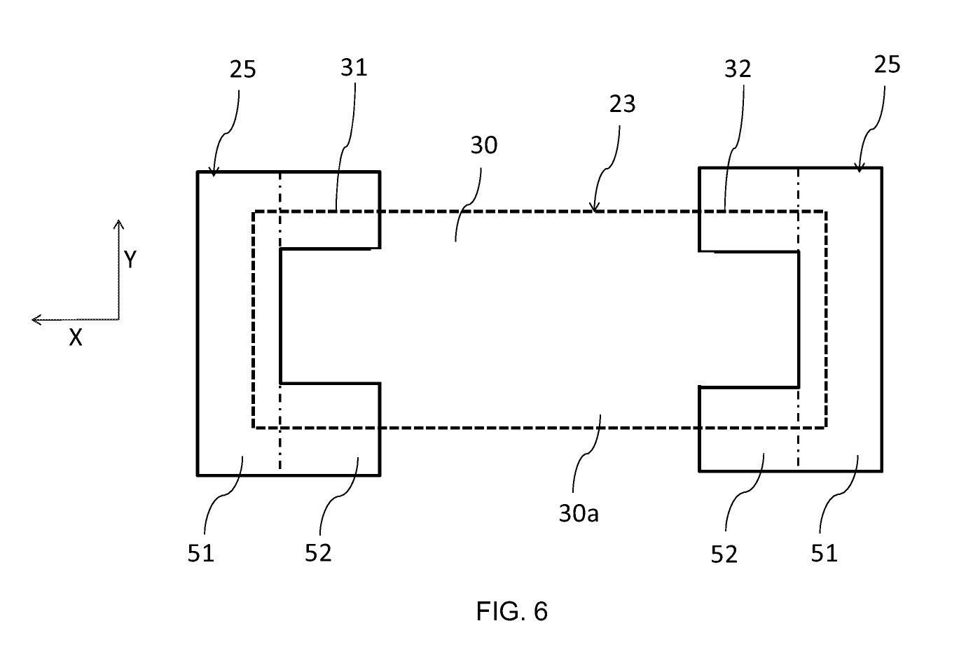

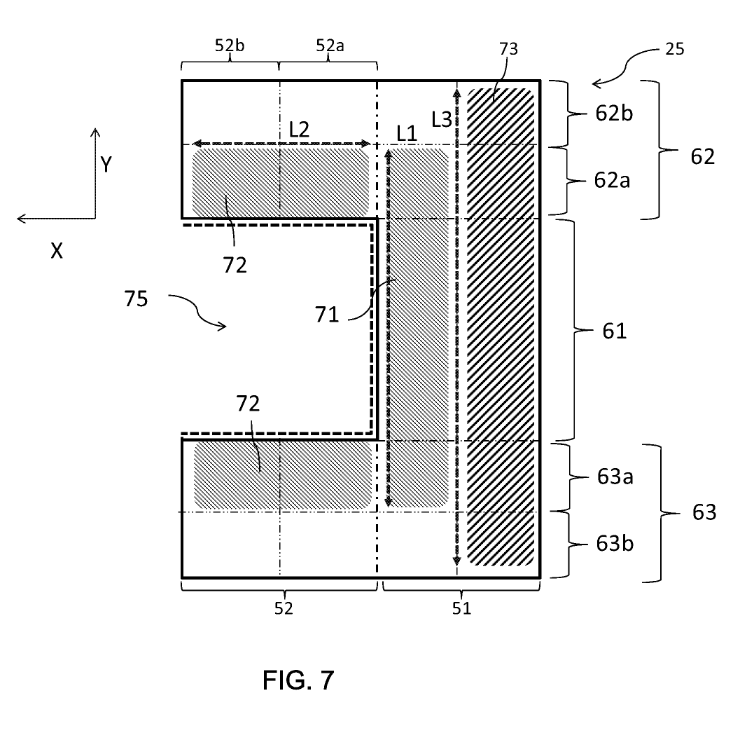

Next, a description of pad 25 is provided with reference to FIG. 6 and FIG. 7.

Each pad 25 may be mounted on printed circuit board 21 corresponding to one or more of the packaged electronic devices 23.

As shown in FIG. 6 and FIG. 7, the pad 25 has first and second pad regions 51 and 52. First pad region 51 is an example of a “first region” of pad 25. Second pad region 52 is an example of “second region” of pad 25. A pair of pads 25 shown in this embodiment may be configured with a shape similar to that of a packaged electronic device 23 mounted thereon. For example, as shown in FIG. 6, a pair of pads 25 are configured for the mounting of a rectangular packaged electronic device 23 thereon.

One first pad region 51 is configured to be aligned with and adjacent to at least a portion of an outer edge of first electrode 31 (i.e., edge 45a in FIG. 6) and another first pad region 51 is configured to be aligned with and adjacent to at least a portion of an outer edge of second electrode 32 (i.e., edge 45a in FIG. 6). The first electrode 31 and the second electrode 32 are each respectively joined electrically and mechanically using a bonding agent 55 to one of the first pad regions 51. Example of bonding agent 55 includes solder, solder paste, or solder paint, etc. for forming an electrically conductive bond.

In addition to a first pad region 51, each pad 25 includes a second pad region 52 that is positioned adjacent to the first pad region 51 of the pad 25. As shown in FIGS. 6 and 7, the first pad region 51 forms an outer edge of pad 25, i.e., an edge of pad 25 that is on the opposite side of and faces away from the second of the pair of pads 25 that together are configured for the mounting of a rectangular packaged electronic device 23 thereon. The second pad region 52 forms an inner edge of pad 25, i.e., an edge of pad 25 that is closest to and faces toward the second of the pair of pads 25. Furthermore, the second edge of pad 25 is positioned to be in contact with the inner edge (i.e., the edge that is opposite edge 45a) of either first electrode 31 or second electrode 32. Vertically, i.e., in the z-axis direction in FIGS. 6 and 7, each of second pad regions 52 are positioned between packaged electronic device 23 and printed circuit board 21.

Thus, an “outer edge of the first electrode 31” refers to the region of the first electrode 31 that is farthest away from the second electrode 32, and an “outer edge of the second electrode 32” refers to the region of the second electrode 32 that is farthest away from the first electrode 31. Furthermore, an “inner edge of the first electrode 31” refers to the region of the first electrode 31 that is closest to the second electrode 32 and an “inner edge of the second electrode 32 refers to the region of the second electrode 32 that is closest to the first electrode 31.

First direction X and second direction Y are now defined. The first direction X and the second direction Y are directions defined to be in the plane of substrate 22 (substrate 22 is shown in FIG. 4). First direction X is the direction in which the second pad region 52 and the first pad region 51 are aligned with each other. Second direction Y is orthogonal with first direction X.

As noted above, a packaged electronic device 23 may be mounted on substrate 22 with two pads 25, each being substantially similar in configuration to the other. In some embodiments, the pads may also be positioned as mirror images of each other, as shown in FIG. 6. For clarity, only a single pad 25 is shown in FIG. 7, i.e., the pad 25 that corresponds to the second electrode 32. Elements of said pad are now described.

The second pad region 52 has a first end portion 52a positioned adjacent first pad region 51 and a second end portion 52b positioned on the side of first end portion 52a opposite first pad region 51. Thus, second end portion 52b is formed on the inner edge of pad 25 and first end portion 52a is formed between second end portion 52b and first pad region 51. In this particular example, first end portion 52a and second end portion 52b form two substantially parallel regions of second pad region 52. Furthermore, first end portion 52a and second end portion 52b are each, in the embodiment illustrated in FIG. 7, divided into two portions, so that an insulating region 75 of pad 25 (i.e., a non-pad region) is formed between the divided portions of first end portion 52a and second end portion 52b.

In addition, first pad region 51 includes three regions: a first region 61, a second region 62, and a third region 63. In this embodiment, first to third regions 61, 62, and 63 are formed together in one contiguous body, but said regions are not limited to such a configuration. Thus, in other embodiments, first to third regions 61, 62, and 63 may be formed in a mutually separated configuration.

As shown in FIG. 7, first region 61 is positioned, for instance, between second region 62 and third region 63. First region 61 is the region corresponding to the center portion of packaged electronic device 23, second region 62 corresponds to a side portion of packaged electronic device 23, and third region corresponds to an opposite side portion of packaged electronic device 23.

As shown in FIG. 7, first region 61 has first side 71 (or first edge) corresponding to at least a portion of edge 45a of second electrode 32 of packaged electronic device 23. Namely, first side 71 is extended substantially in parallel to edge 45a of second electrode 32 of packaged electronic device 23 and is in contact with edge 45a of second electrode 32 of packaged electronic device 23.

Furthermore, “corresponding to at least a portion of edge 45a of second electrode 32” is not limited to the case of completely overlapping or coming into contact with edge 45a, but includes being positioned near the edge 45a (for instance, in vicinity). Furthermore, “corresponding to edge 45a” is not limited to cases in which the entire length of edge 45a is positioned proximate region 61

Second region 62 and third region 63 are regions corresponding to a corner portion 45b of packaged electronic device 23. As shown in FIG. 7, second region 62 and third region 63 are disposed adjacent to second pad region 52 (i.e., the portion of pad 25 adjacent to insulating region 75) and first pad region 51. More specifically, second region 62 and third region 63 each have first portions 62a, 63a disposed adjacent to ends of first region 61 and aligned therewith in second direction Y. In addition, second region 62 and third region 63 each have second portions 62b, 63b that are not adjacent to ends of first region 61. First portions 62a, 63a and second portions 62b, 63b are located at positions adjacent to second pad region 52 and are substantially aligned with second pad region 52 in first direction X.

As shown in FIG. 7, the second pad region 52 includes a second side portion 72 disposed in contact with at least a portion of edges 45b and 45c of second electrode 32 of packaged electronic device 23, respectively (edges 45b and 45c are shown in FIG. 5). Namely, the second side 72 extends substantially parallel to edges 45b, 45c of second electrode 32 of packaged electronic device 23, and lies adjacent to edges 45b, 45c of second electrode 32.

As shown in FIG. 7, the side length of first edge portion 52a of second pad region 52 is configured to fit packaged electronic device 23 or other parts to be mounted on pad 25. In the embodiment illustrated in FIG. 7, length L1 of first side 71, length L2 of second side 72, and length L3 of third side 73 shows an example in which each of lengths L1-L3 are substantially equal in length.

As shown in FIG. 7, substrate 22 has insulating region 75 (which is a non-pad region) disposed in and formed by a gap between the divided portions of first end portion 52a and second end portion 52b. Insulating region 75 is configured with a concave shape, such as a U-shape, a V-shape, an L-shape, or other convex form, and is disposed adjacent first pad region 51 and second pad region 52 of pad 25. The insulating region 75 may be coated with a solder resist or other solder masking material so that the bonding agent 55 selectively spreads to the first pad region 51 of the pad 25. Specifically, the presence of the solder resist in insulating region 75 causes spreading of the bonding agent 55 to be biased to the side of the pad 25 opposite to the center portion of packaged electronic device 23 (i.e., biased to the outer edge of pad 25 corresponding to the first pad region 51. As shown in FIG. 7, packaged electronic device 23 is joined to first region 61, first portion 62a of second region 62 and a portion of first portion 63a of third region 63 by the bonding agent 55.

Next, an explanation is given on the behavior of pad 25.

Packaging of packaged electronic device 23 to pad 25 is carried out by pre-feeding a bonding agent 55 such as solder onto the pad 25 and melting the bonding agent 55 in a reflow process so that first electrode 31 and second electrode 32 of packaged electronic device 23 are bonded to the pad 25. The bonding agent 55 is melted in the reflow process to a liquid state and spreads over pad 25. Then, due to surface tension generated at the side 73, the bonding agent 55 from sides 71, 72 of pad 25 accumulates along the side 73.

Furthermore, bonding agent 55, when molten, is wicked via surface tension onto first pad region 51 (particularly over first to third regions 61, 62, 63), so that very little or no residual bonding agent 55 remains between second pad region 52 and rear surface 30a of packaged electronic device 23. For convenience of explanation, individual phenomenon is explained by paying attention to surface tension generating in specific region.

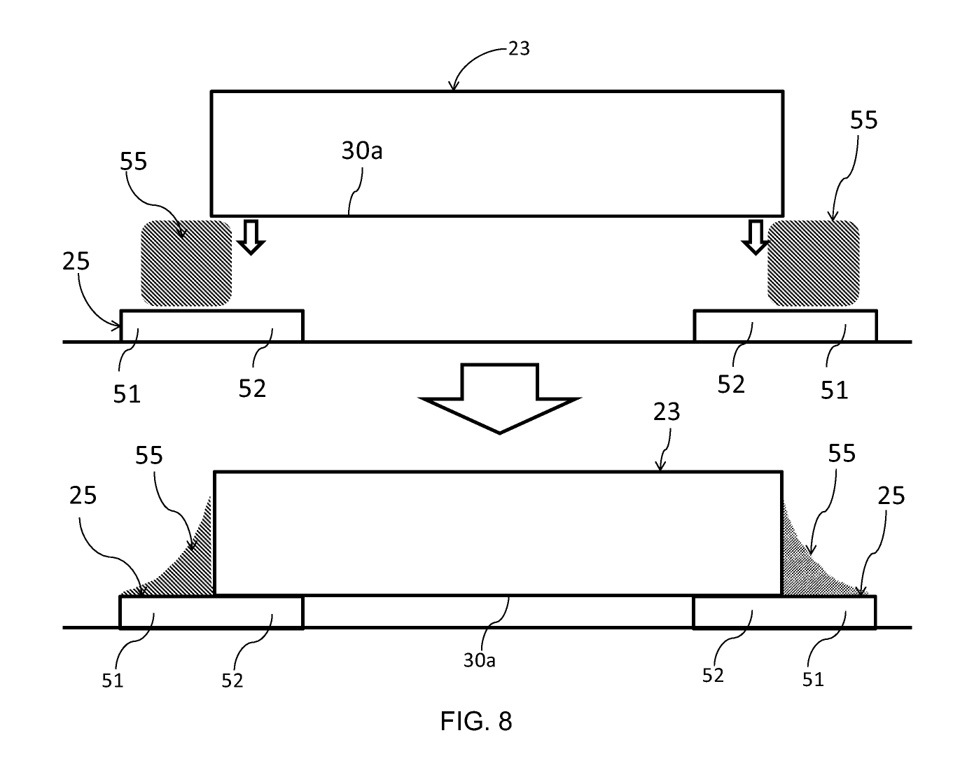

As shown in FIG. 8, in one instance of mounting packaged electronic device 23, the position of second electrode 32 of packaged electronic device 23 is readily stabilized in a desired location by surface tension of the bonding agent 55 coated on the side 73. Namely, in order for packaged electronic device 23 to be displaced from an optimal during the mounting process, for example when first side 71 of second electrode 32 is displaced toward the inner side of first pad region 51 (i.e., into insulating region 75), surface tension generated by the presence of the bonding agent 55 on side 73 must be overcome. Consequently, shifts in position of packaged electronic device 23 are prevented and packaged electronic device 23 remains with edge 45a of the second electrode 32 positioned adjacent to side 73.

Furthermore, the bonding agent 55 is generally does not coat sides 71, 72 of pad 25. In other words, the bonding agent 55 is generally absent from the region where pad 25 and packaged electronic device 23 are mutually overlapped.

In this configuration, the thickness mounting height of bonding agent 55 in the region where pad 25 and packaged electronic device 23 are mutually overlapped can be substantially prevented, and shifting in position of packaged electronic device 23 also can be inhibited.

In this embodiment, insulating region 75 is positioned adjacent to the portion of packaged electronic device 23 overlapping with pad 25. Since molten bonding agent 55 spreads along the surface of the metallic surface of pad 25 during the reflow process, bonding agent 55 avoids flowing into insulating region 75. As a result, the bonding agent 55 spreads away from the inner edge of pad 25 formed by second pad region 52 and toward the first pad region 51 of the pad 25. Even when a small amount of the bonding agent 55 enters into the gap between pad 25 and the rear surface 30 (shown in FIGS. 5 and 6) of packaged electronic device 23, in the region of insulating region 75, the height from the surface of substrate 22 is lower than that of the pad 25. Thus, since insulating region 75 forms a depressed region, bonding agent 55 that flows toward the center portion of packaged electronic device 23 collects in insulating region 75. Consequently, this configuration facilitates component mounting having a low profile without restricting the amount of bonding agent 55 used.

Alternate methods of mounting packaged electronic device 23 so as to reduce thickness of bonding agent 55 are generally less effective than that described herein. For example, a method of restricting the coating amount to the minimum amount or a method of increasing water content in bonding agent to make the concentration thin (i.e., a method of controlling volumetric resistance) is can also be implemented to reduce thickness of bonding agent 55, but these methods have drawbacks. In those cases, however, when mounting packaged electronic device 23 onto pad 25, the packaged electronic device 23 is positioned by a balance of surface tension of bonding agent 55 in first and second pad regions 51, 52 when the bonding agent 55 is in a liquid state in the reflow process. In such an instance, packaged electronic device 23 generally moves to make an edge of the electrode overlap on an edge of the pad. Thus there is a possibility of causing position shifting of a part or a possibility of causing electrical connection instability.

Pad 25 of this embodiment is provided with first pad region 51 and second pad region 52 having a portion projected toward first pad region 51, and insulating region 75 which is a guide to prevent flow of bonding agent 55 to the center of packaged electronic device 23 or as a concave portion disposed between first pad region 51 and second pad region 52 for encouraging flow of bonding agent 55 away from first pad region 51.

As shown in FIG. 8, the region, where bonding agent 55 is deposited, is the region lying a slightly outside of edge 45a of packaged electronic device 23 in first pad region 51, and extends for a height (i.e., a thickness of the bonding agent) onto the side surface of packaged electronic device 23. When the bonding agent 55 is melted in the reflow process to mount packaged electronic device 23, and spreads along the surface of pad 25. Since insulating region 75 is located in the region of pad 25 extending to the rear surface 30 of packaged electronic device 23, the bonding agent 55 spreads along the surface of packaged electronic device 23 by avoiding the rear surface 30 of packaged electronic device 23. Furthermore, even when a small portion of the bonding agent 55 is located in the region between packaged electronic device 23 and substrate 22 (pad 25), the bonding agent flows into insulating region 75. According to this configuration, a portion of coated bonding agent 55 comes in contact with an outer side surface of packaged electronic device 23, such as edge 45a of packaged electronic device 23 in first pad region 51. Since bonding agent 55 is initially applied on an outer side surface of packaged electronic device 23 and very little is disposed between packaged electronic device 23 and pad 25, the formation of a fillet is biased to the outer side surface, as shown in FIG. 8. A portion of the bonding agent 55 that may get between packaged electronic device 23 and substrate 22 and pad 25 flows into insulating region 75. Thus, the distance between packaged electronic device 23 and substrate 22 (and pad 25) is relatively small, and the mounting of components having low profile can be realized without restricting the coating amount of the bonding agent 55. Furthermore, the position of packaged electronic device 23 is easily stabilized and position shifting hardly occurs due to surface tension being generated at third side 73 by the bonding agent 55.

In this embodiment, pad 25 has first side 71 and second side 72 corresponding to at least a portion of electrode 32 of packaged electronic device 23. According to this embodiment, the position of packaged electronic device 23 is easily stabilized by first side 71 and second side 72.

In this embodiment, the second pad region 52 is expanded to extend past outer side than edges 45b, 45c of electrode 32 of packaged electronic device 23. According to this embodiment, packaged electronic device 23 is stabilized at the position where edge 45a of electrode 32 is adjacent to first side 71. In addition, packaged electronic device 23 is stabilized at the position where edge 45b of electrode 32 is adjacent to second side 72. Thereupon, the position shifting of packaged electronic device 23 is easily suppressed by a pair of pad 25. The position shifting of packaged electronic device 23 is further suppressed since first side 71 and second side 72 can function as guides for a particular position for packaged electronic device 23.

In this embodiment, first side 71, second side 72, and third side 73 have approximately the same length. According to this configuration, surface tension can be dispersed nearly uniformly. Thus, the position of packaged electronic device 23 is further stabilized.

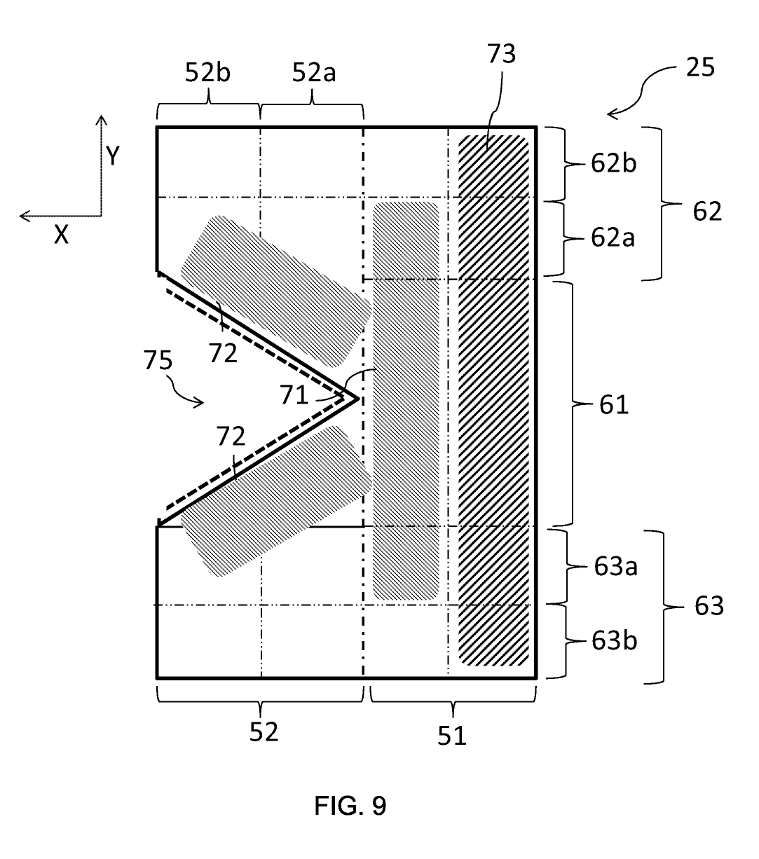

Next, several modification examples are explained by referring to FIG. 9 to FIG. 11.

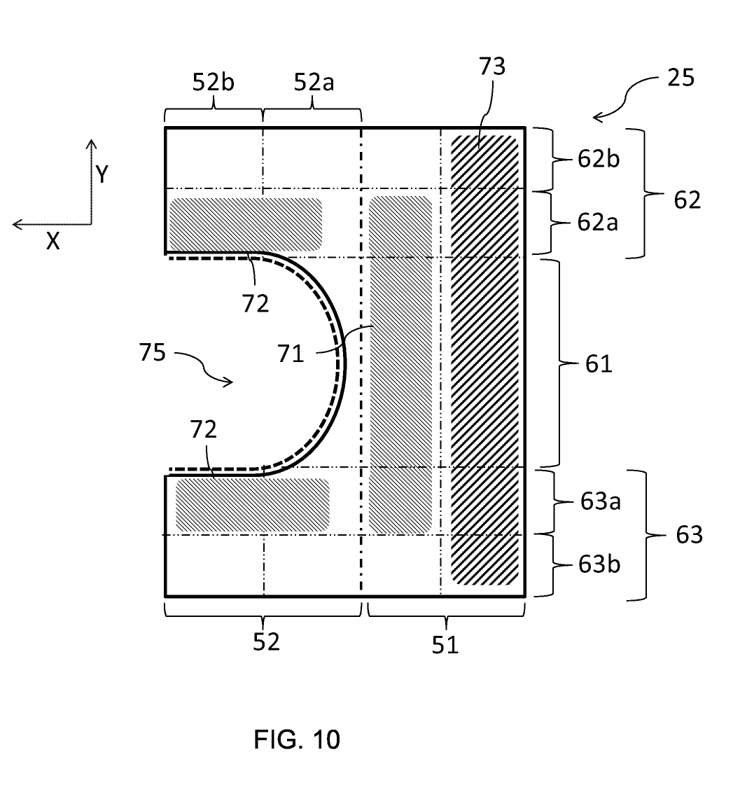

As shown in FIGS. 9 and 10, insulating region 75, while formed as a concave region, may have a circular arc configuration or a triangular shape instead of a rectangular outer edge shape. Even in such configurations, the same effect as in the embodiment described above can be obtained.

As shown in FIG. 10, second pad 52 does not have to project from two different ends of first pad region 51. Namely, the insulating region 75 is formed by an outer edge of first pad region 51 and an outer edge of second pad region 52, and may be a concave portion, in which the bonding agent 55 can be spread on pad 25 along the outer edge and a side surface of packaged electronic device 23. Even in this configuration, the same effect as in the previously described embodiments can be obtained.

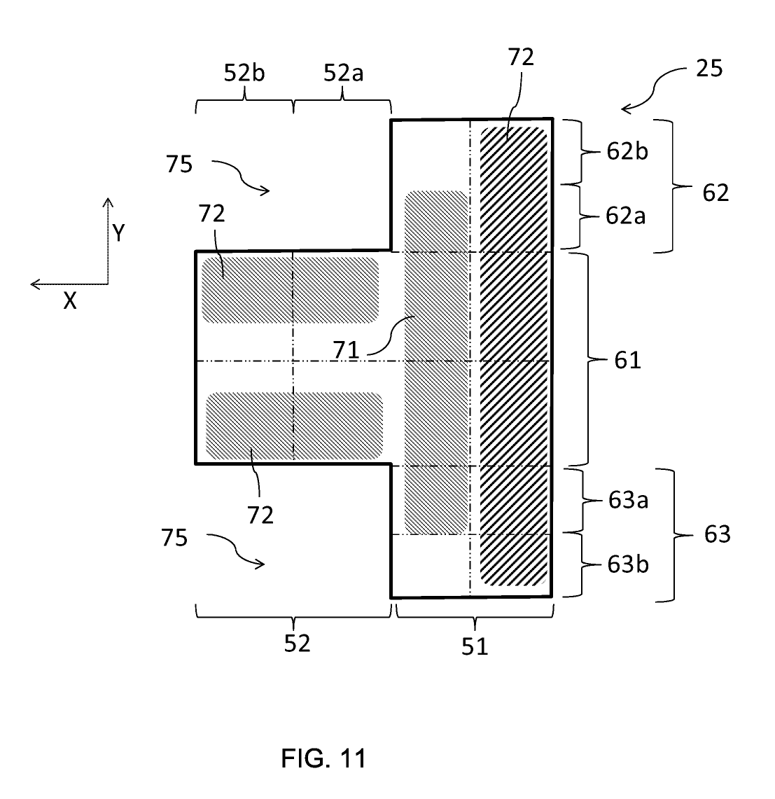

As shown in FIG. 11, in pad 55, second pad region 52 does not have to project from both ends of first pad region 51. Namely, may have a configuration in which the insulating region 75 is formed by an outer edge of first pad region 51 and an outer edge of second pad region 52, and the bonding agent 55 can be spread by biasing to the side opposite to center portion of packaged electronic device 23. Even in this configuration, the same effect as in the embodiments described above can be obtained.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a casing;
a substrate having housed in the casing and having a mounting pad formed thereon;
a packaged electronic device having a mounting surface coupled to the mounting pad and an electrode formed on a side surface of the packaged electronic device; and
a conductive material that is disposed on a portion of the electrode formed on a side surface of the packaged electronic device and on a portion of the mounting pad, and electrically joins the mounting pad and the electrode,
wherein the mounting pad includes a first region and a second region, the first region being aligned with and adjacent to at least a portion of an outer edge of the electrode, and the second region being positioned between the mounting surface of the packaged electronic device and the substrate and having at least one concave component that forms an insulating region disposed on a side of the second region that is opposite the first region.

2. The electronic device according to claim 1, wherein the conductive material forms a fillet in contact with the portion of the mounting pad and the portion of the electrode formed on the side surface.

3. The electronic device according to claim 2, wherein substantially none of the conductive material is disposed between the second region and the mounting surface.

4. The electronic device according to claim 1, further comprising another mounting pad disposed proximate the second region, wherein the side surface of the packaged electronic device on which the electrode is formed is disposed on a side of the packaged electronic device that is opposite to the another mounting pad.

5. The electronic device according to claim 4, wherein the another mounting pad includes a third region and a fourth region, the third region being disposed between the second region and the fourth region and having at least one concave component that forms an insulating region disposed on a side of the third region that is opposite the fourth region.

6. The electronic device according to claim 5, wherein the concave part is configured so that the insulating region disposed on the side of the third region that is opposite the fourth region faces the insulating region disposed on the side of the second region that is opposite the first region.

7. The electronic device according to claim 5, wherein the mounting pad and the another mounting pad each have substantially the same configuration.

8. The electronic device according to claim 7, wherein the another mounting pad is positioned as a mirror image of the mounting pad.

9. The electronic device according to claim 1, wherein the insulating region is configured to selectively spread the conductive material to the first region during a reflow process.

10. The electronic device according to claim 9, wherein the insulating region includes at least one of a U-shape, a V-shape, and an L-shape.

11. The electronic device according to claim 1, wherein the insulating region includes a solder masking material.

12. A circuit board comprising:
a substrate having a mounting pad formed thereon,
a packaged electronic device having a mounting surface coupled to the mounting pad and an electrode formed on a side surface of the packaged electronic device, and
a conductive material that is disposed on a portion of the electrode formed on the side surface of the packaged electronic device and on a portion of the mounting pad, and electrically joins the mounting pad and the electrode,
wherein the mounting pad includes a first region and a second region, the first region being aligned with and adjacent to at least a portion of an outer edge of the electrode and including the portion of the mounting pad, and the second region being positioned between the mounting surface of the packaged electronic device and the substrate and having at least one concave component that forms an insulating region disposed on a side of the second region that is opposite the first region.

13. The electronic device according to claim 12, wherein the conductive material forms a fillet in contact with the portion of the mounting pad and the portion of the electrode formed on the side surface.

14. The electronic device according to claim 13, wherein substantially none of the conductive material is disposed between the second region and the mounting surface.

15. The electronic device according to claim 12, further comprising another mounting pad disposed proximate the second pad region, wherein the side surface of the packaged electronic device on which the electrode is formed is disposed on a side of the packaged electronic device that is opposite the another mounting pad.

16. The electronic device according to claim 15, wherein the another mounting pad includes a third region and a fourth region, the third region being disposed between the second region and the fourth region and having at least one concave component that forms an insulating region disposed on a side of the third region that is opposite the fourth region.

17. The electronic device according to claim 16, wherein the concave part is configured so that the insulating region disposed on the side of the third region that is opposite the fourth region faces the insulating region disposed on the side of the second region that is opposite the first region.

18. The electronic device according to claim 16, wherein the mounting pad and the another mounting pad each have substantially the same configuration.

19. The electronic device according to claim 18, wherein the another mounting pad is positioned as a mirror image of the mounting pad.

20. The electronic device according to claim 12, wherein the insulating region is coated with an insulating paint that includes a solder masking material.
